(19) United States
(12) Patent Application Publication
(10) Pub. No.: US 2015/0179489 A1
(43) Pub. Date: Jun. 25, 2015

(54) Substrate Processing Module, Substrate Processing Apparatus Including the same, and Substrate Transferring Method

(71) Applicant: Eugene Technology Co., Ltd., Yongin-si (KR)

(72) Inventors: Jun-Jin Hyon, Gunpo-si (KR); Byoung-Gyu Song, Yongin-si (KR); Kyong-Hun Kim, Yongin-si (KR); Yong-Ki Kim, Pyeongtaek-si (KR); Yang-Sik Shin, Yongin-si (KR); Chang-Dol Kim, Yongin-si (KR)

(21) Appl. No.: 14/573,514

(22) Filed: Dec. 17, 2014

(30) Foreign Application Priority Data
Dec. 20, 2013 (KR) 10-2013-0160268

(51) Int. Cl. H01L 21/677; C23C 16/458

(52) U.S. Cl. CPC H01L 21/67745; C23C 16/4584; C23C 16/4585; H01L 21/67748; H01L 21/67751

(57) ABSTRACT

There are provided a substrate processing module, and substrate processing apparatus including the same, and a substrate transferring method. The substrate processing module includes: a chamber having a passage formed on one side thereof and allowing a substrate to enter or exit therethrough; a first susceptor installed within the chamber, having at least one through hole formed in an upper surface thereof, and allowing the substrate to be placed thereon; a second susceptor installed within the chamber and allowing the substrate to be placed thereon; a rotary member provided within the chamber and rotating, based on a preset position; a holder connected to the rotary member and having a mounting surface allowing the substrate to be placed thereon; and a holder driving module driving the rotary member to move the holder to a standby position corresponding to the first susceptor or to a delivery position corresponding to the second susceptor.

### CROSS-REFERENCE TO RELATED APPLICATION

This application claims the benefit of Korean Patent Application No. 10-2013-0160268 filed on Dec. 20, 2013, with the Korean Intellectual Property Office, the disclosure of which is incorporated herein by reference.

### BACKGROUND

1. Field of the Invention

The present disclosure relates to a substrate processing module, a substrate processing apparatus including the same, and a substrate transferring method, and more particularly, to a substrate processing module allowing for an increase in an amount of substrates within a chamber, and substrate processing apparatus including the same.

In general, in a substrate processing apparatus based on a chemical vapor deposition process, a transfer robot is used to transfer two or more wafers to susceptors of a chamber in order to process the two or more wafers within the single chamber.

2. Description of Related Art

Korean Patent Laid-Open Publication No. 2007-0080767 dated Aug. 13, 2007 is of background interest.

### SUMMARY OF THE INVENTION

An aspect of the present disclosure may provide a substrate processing module for simultaneously performing processing on a plurality of substrates, a substrate processing apparatus including the same, and a substrate transferring method.

An aspect of the present disclosure may also provide a substrate processing module for effectively loading a plurality of substrates into or unloading a plurality of substrates from a chamber, a substrate processing apparatus including the same, and a substrate transferring method.

Other aspects of the present invention will become apparent through embodiments described hereinafter in conjunction with the accompanying drawings.

According to an aspect of the present disclosure, a substrate processing module may include: a chamber having a passage formed on one side thereof and allowing a substrate to enter or exit therethrough; a first susceptor installed within the chamber, disposed in front of the passage, having at least one through hole formed in an upper surface thereof in a penetrating manner, and allowing the substrate to be placed thereon during a process; a second susceptor installed within the chamber, disposed to the rear of the first susceptor, and allowing the substrate to be placed thereon during a process; a rotary member provided within the chamber and rotating, based on a preset position; a holder connected to the rotary member, rotating together with the rotary member, and having a mounting surface allowing the substrate to be placed thereon; and a holder driving module connected to the rotary member and driving the rotary member to move the holder to a standby position corresponding to a position of the first susceptor or to a delivery position corresponding to a position of the second susceptor.

According to another aspect of the present disclosure, a substrate processing module may include: a chamber having a first process space and a second process space divided by a partition and having a first passage and a second passage formed on one side thereof and allowing substrates to enter and exit the first process space and the second process space, respectively; first and third susceptors installed within the chamber, disposed in front of the first passage and in front of the second passage, respectively, having at least one through hole formed in upper surfaces thereof in a penetrating manner, and allowing the substrates to be placed thereon during a process; second and fourth susceptors installed within the chamber, disposed to the rear of the first susceptor and the third susceptor, respectively, and allowing the substrates to be placed thereon during a process; a first rotary member and a second rotary member installed within the chamber, and rotating, based on preset positions, respectively; a first holder connected to the first rotary member to rotate together therewith and having a mounting surface allowing the substrates to be placed thereon; a second holder connected to the second rotary member to rotate together therewith and having a mounting surface allowing the substrates to be placed thereon; a first holder driving module connected to the first rotary member to drive the first rotary member, and moving the first holder to a first standby position corresponding to the first susceptor or a first delivery position corresponding to the second susceptor; a second holder driving module connected to the second rotary member to drive the second rotary member, and moving the second holder to a second standby position corresponding to the third susceptor or a second delivery position corresponding to the fourth susceptor; at least one lift pin installed below the first and third susceptors, respectively, and moving through the at least one through hole; and a lift pin driving module connected to the at least one lift pin and moving the at least one lift pin between a lift pin accommodation level and a lift pin loading level, wherein an upper end of the at least one lift pin is positioned to be higher than the first and third susceptors at the lift pin accommodation level, and the mounting surface is positioned to be lower than the upper surfaces of the first and third susceptors at the lift pin loading level.

According to another aspect of the present disclosure, a substrate processing apparatus may include: a load lock chamber allowing a substrate transferred from the outside to be placed thereon and having an interior changing from a vacuum state to an atmospheric pressure state; a substrate processing module performing processing on the substrate; and a substrate transfer module disposed between the load lock chamber and the substrate processing module and having a substrate transfer robot transferring the substrate between the load lock chamber and the substrate processing module, wherein the substrate processing module includes: a chamber having a passage formed on one side thereof and allowing a substrate to enter or exit therethrough; a first susceptor installed within the chamber, disposed in front of the passage, having at least one through hole formed in an upper surface thereof in a penetrating manner, and allowing the substrate to be placed thereon during a process; a second susceptor installed within the chamber, disposed to the rear of the first susceptor, and allowing the substrate to be placed thereon during a process; a rotary member provided within the chamber and rotating, based on a preset position; a holder connected to the rotary member, rotating together with the rotary member, and having a mounting surface allowing the substrate to be placed thereon; and a holder driving module connected to the rotary member and driving the rotary member to move the holder to a standby position corresponding to the first susceptor or to a delivery position corresponding to the second susceptor.

According to another aspect of the present disclosure, a substrate transferring method for transferring a substrate by using the foregoing substrate processing module may include: a first mounting operation of placing a first substrate on a first susceptor; a first changing operation of changing a holder in a standby position from a holder loading level to a holder accommodation level; a first moving operation of rotating the holder to move to a delivery position; a second changing operation of changing the holder in the delivery position from the holder accommodation level to the holder loading level; and a second mounting operation of placing a second substrate on the first susceptor.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a view schematically illustrating a substrate processing apparatus according to an exemplary embodiment of the present disclosure;

FIG. 2 is a view schematically illustrating a substrate processing module illustrated in FIG. 1;

FIG. 3 is a cross-sectional view taken along line A-A of FIG. 2;

FIG. 4 is a cross-sectional view taken along line B-B of FIG. 2;

FIG. 5 is a view illustrating a susceptor illustrated in FIG. 2;

FIG. 6 is a view illustrating a holder illustrated in FIG. 2; and

FIGS. 7A through 8E are views illustrating operations of the holder illustrated in FIG. 2.

### DETAILED DESCRIPTION OF THE INVENTION

Hereinafter, exemplary embodiments of the present disclosure will be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

Hereinafter, a deposition process is described in an exemplary manner, but the present disclosure may be applicable to various processes, including deposition process.

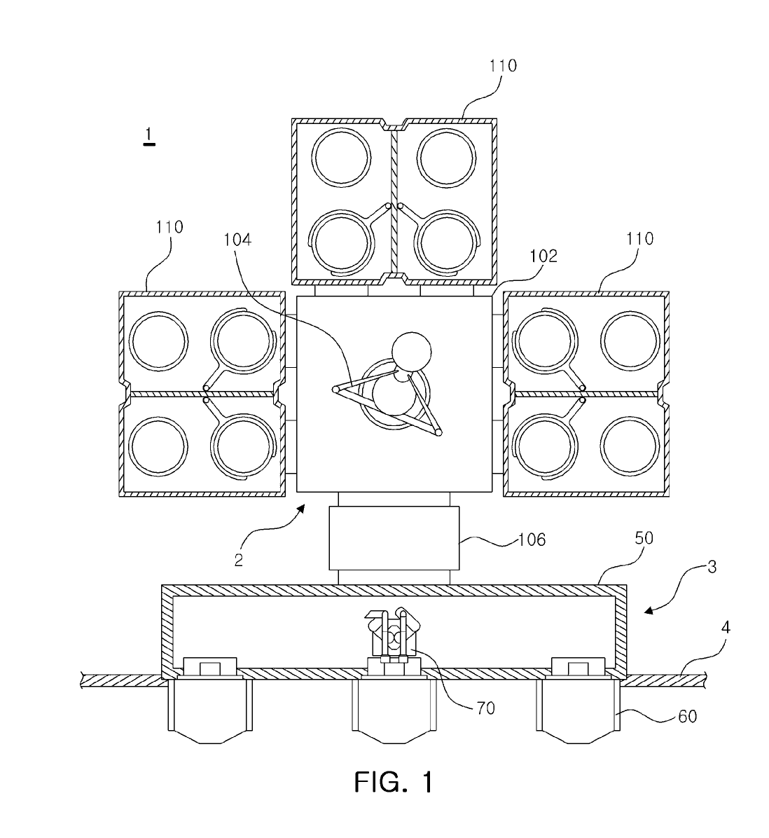

FIG. 1 is a view schematically illustrating a substrate processing apparatus according to an exemplary embodiment of the present disclosure. A substrate processing apparatus 1 includes process equipment 2, an equipment front end module (EFEM) 3, and an interface wall 4. The EFEM 3 is installed in front of the process equipment 2 to transfer substrates between a container (not shown) accommodating the substrates and the process equipment.

The EFEM 3 includes a plurality of loading ports 60 and a frame 50. The frame 50 is positioned between loading ports 60 and the process equipment 2. The container accommodating substrates are placed on the loading ports 60 by a transfer unit (not shown) such as an overhead transfer unit, an overhead conveyor unit, or an automatic guided vehicle.

The container may be an airtight container such as a front open unified pod (FOUP). A frame robot 70 transferring substrates between the container placed on the loading ports 60 and the process equipment 2 is installed within the frame 50. A door opener (not shown) automatically opening and closing a door of the container may be installed in the frame 50. Also, a fan filter unit (FFU) (not shown) supplying clean air to an interior of the frame 50 such that clean air flows downwardly (i.e., from top to bottom) within the frame 50 may be provided in the frame 50.

A predetermined process for processing substrates is performed in the process equipment 2. The process equipment 2 includes a substrate transfer module 102, a load lock chamber 106, and substrate processing modules 110. The substrate transfer module 102 has a substantially polygonal shape when viewed from above, and the load lock chamber 106 and the substrate processing modules 110 are installed on the side of the substrate transfer module 102.

The load lock chamber 106 is positioned on the side, among the sides of the substrate transfer module 102, adjacent to the EFEM 3. Substrates temporarily remain within the load lock chamber 106 and are loaded into the process equipment 2 to undergo processing, and after the processing is completed, the substrates are unloaded from the process equipment 2 and temporarily remain within the load lock chamber 106. Interiors of the substrate transfer module 102 and the substrate processing modules 110 are maintained in a vacuum state, and the load lock chamber 106 is changed to be in a vacuum state or to have atmospheric pressure. The load lock chamber 106 prevents external contaminants from being introduced to the interiors of the substrate transfer module 102 and the substrate processing modules 110 Also, when the substrates are being transferred, the substrates are not exposed to the air, preventing the growth of oxide films on the substrates.

Gate valves (not shown) are installed between the load lock chamber 106 and the substrate transfer module 102 and between the load lock chamber 106 and the EFEM 3. When substrates are transferred between the EFEM 3 and the load lock chamber 106, the gate valve provided between the load lock chamber 106 and the substrate transfer module 102 is closed, and when the substrates are transferred between the load lock chamber 106 and the substrate transfer module 102, the gate valve provided between the load lock chamber 106 and the EFEM 3 is closed.

The substrate transfer module 102 includes a substrate transfer robot 104. The substrate transfer robot 104 transfers substrates between the load lock chamber 106 and the substrate processing modules 110. When the substrate transfer module 102 transfers substrates, the substrate transfer module 102 is hermetically sealed to maintain vacuum. Maintaining vacuum is to prevent the substrates from being exposed to contaminants (e.g., 02, particulate matter, and the like).

The substrate processing modules 110 are provided to deposit a thin film on a substrate. FIG. 1 illustrates three substrate processing modules 110, but the present disclosure is not limited thereto and four or more substrate processing modules 110 may be provided. Also, a module performing a different process (for example, cleansing or etching) may be installed on the side of the substrate transfer module 102.

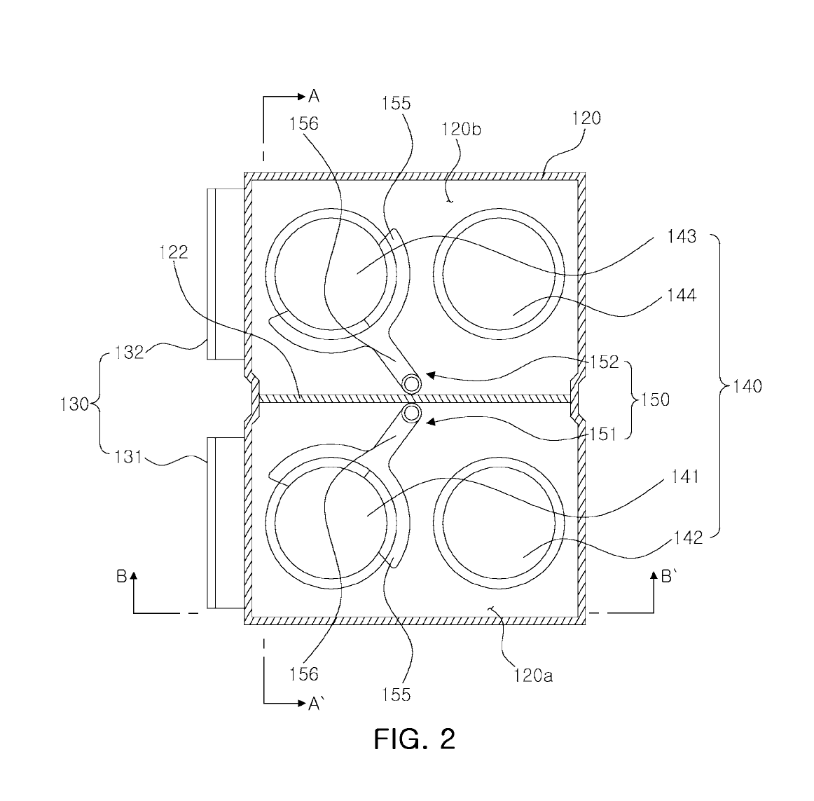

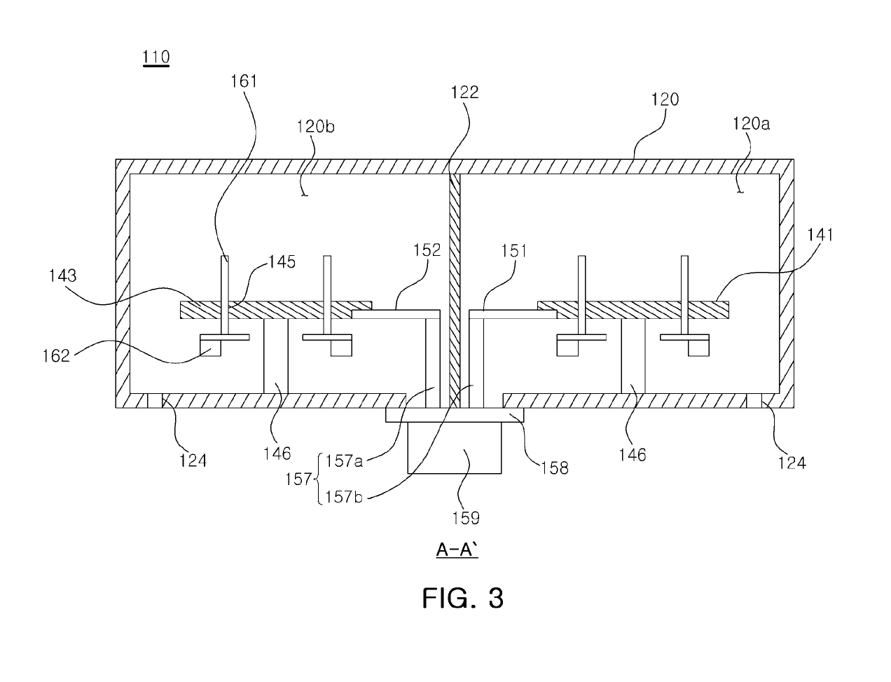

FIG. 2 is a view schematically illustrating the substrate processing module illustrated in FIG. 1, and FIG. 3 is a cross-sectional view taken along line A-A of FIG. 2. As illustrated in FIG. 2, the substrate processing module 110 includes a chamber 120 having a passage 130 allowing substrates W to enter and exit therethrough. The chamber 120 provides a process space, and a process for the substrates W is performed within the process space. A partition 122 is installed within the chamber 120, and the process space of the chamber 120 is divided into a first process space 120a and a second process space 120b by the partition 122.

The chamber 120 may have a passage 130 formed on one side thereof, and the substrates W enter the chamber 120 through the passage 130. Namely, a first passage 131 is formed on one side of the chamber 120 corresponding to the first process space 120a, and a second passage 132 is formed on one side of the chamber 120 corresponding to the second process space 120b. A gate valve 170 may be installed on an outer side of the first and second passages 131 and 132, and the first and second passages 131 and 132 may be opened or closed by the gate valve 170. As discussed above, the substrate transfer robot 104 moves together with the substrates W to the interior of the chamber 120 through first and second passages 131 and 132, mounts the substrates W on upper ends of lift pins 161 or forks 155 as described hereinafter, and moves from the chamber 120 through the first and second passages 131 and 132. Here, the first and second passages 131 and 132 are opened by the gate valve 170.

As illustrated in FIGS. 2 and 3, a plurality of susceptors 140 are installed within the chamber 120. First and second susceptors 141 and 142 are sequentially disposed to be parallel in a direction in which the substrates W are led in. The first susceptor 141 is disposed in a position corresponding to the first passage 131, and the second susceptor 142 is disposed inwardly of the first susceptor 141. Also, third and fourth susceptors 143 and 144 are sequentially disposed to be parallel in the direction in which the substrates W are led in. The third susceptor 143 is disposed in a position corresponding to the second passages 132, and the fourth susceptor 144 is disposed inwardly of the third susceptor 143.

The substrates W are moved to the interior of the chamber 120 through the substrate transfer robot 104, and when the process is performed, the substrates W are placed on the first to fourth susceptors 141, 142, 143, and 144. The first to fourth susceptors 141, 142, 143, and 144 are supported by support shafts 146, and the support shafts 146 are fixed to a lower surface of the chamber 120.

As illustrated in FIG. 2, the first susceptor 141 and the third susceptor 143 are respectively positioned in front of the first passage 131 and the second passage 132 (namely, the portions to which the substrates W are led in to the interior f the chamber 120 through the passages 131 and 132). Processes are initiated in a state in which a single substrate W is placed on every susceptor, and here, the processes may be simultaneously performed on the substrates W, respectively. Thus, the processes may be completed for four substrates W, whereby productivity may be promoted.

Meanwhile, as described above, the substrates W may be transferred to the interior of the chamber 120 via the substrate transfer robot 104, the substrate transfer robot 104 placing the substrates W on the lift pins 161 or the forks 155.

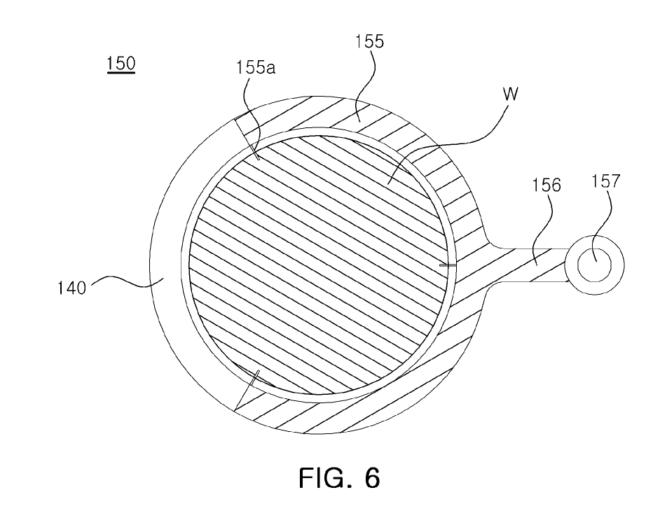

As illustrated in FIGS. 2 and 6, the fork 155 of a holder 150 may be connected to a rotational shaft 157 via an arm 156 and may rotate based on the center (or a preset position of the chamber 120) of the rotational shaft 157. Here, the fork 155 may have a circular arc shape surrounding the edges of the substrate W, specifically, an arc shape (or a fan shape). In addition, the fan shape may have a central angle of 180 degrees or greater to provide stability when the substrate W is picked up and transferred. The rotational shaft 157 penetrates through a lower wall of the chamber 120, is installed in a pre-set center of the chamber 120, and rotates on the preset center. The rotational shaft 157 is connected to a holder driving module 159 and lifted or lowered and rotated by the holder driving module 159. Holders 151 and 152 are lifted and lowered and rotated together with the rotational shaft 157. The holder driving module 159 is fixed to a support plate 158 fixedly installed on a lower wall of the chamber 120.

The rotational shaft 157 is provided in an internal space of the chamber 120. The rotational shaft 157 is positioned at the end of the chamber 120 in a width direction of the chamber 120 based on a direction in which the substrates W enters and exits the passage 130, and is disposed in the center of the chamber 120 in a longitudinal direction of the chamber 120. For example, a first process space 120a of the chamber 120 has a width equal to that of the first process space 120a in a direction in which the substrates enter the first passage 131 and a length of the first process space 120a in a direction perpendicular to the entry direction. Here, a first rotational shaft 157a is disposed in the center of the length of the first process space 120a and disposed at both ends of the width of the first process space 120a. A distance from the first rotational shaft 157a to the center of the first susceptor 141 and a distance from the first rotational shaft 157a to the center of the second susceptor 142 may be equal. Accordingly, the first holder 151 connected to the first rotational shaft 157a may accurately move the substrate W from the first susceptor 141 to the second susceptor 142. A distance between the first rotational shaft 157a and the first susceptor 141 may be smaller than the width of the first process space 120a. So far, the first rotational shaft 157a has been described, and here, a second rotational shaft 157b installed in the second process space 120b may have a configuration and operational effect identical to those of the first rotational shaft 157a.

The first and second holders 151 and 152 may be respectively positioned in front of the first and second passages 131 and 132 by rotation (“standby position”) or may be positioned behind the first and second passages 131 and 132 (“delivery position”). Namely, the first and second holders 151 and 152 may rotate to be placed in the standby positions corresponding to the first and third susceptors 141 and 143 or in the delivery positions corresponding to the second and fourth susceptors 142 and 144. The substrate transfer robot 104 may place the substrates W on the upper ends of the lift pins 161 of the first and third susceptors 141 and 143. Also, the substrate transfer robot 104 may place the substrates W on the first and second holders 150 positioned in the standby positions, and here, the substrates W are placed on upper surfaces of support pins 155a as described hereinafter. Upon receiving the substrates W, the holders 150 may rotate to move from the standby positions to the delivery positions.

Meanwhile, when the holders 150 move to the delivery positions, the holders 151 and 152, on which substrates W are to be placed, may not be positioned in the first and third susceptors 141 and 143. Here, the lift pins 161 disposed below the first and third susceptors 141 and 143 respectively penetrate through holes 145 in a penetrating manner to receive substrates W from the substrate transfer robot 104. In this manner, a plurality of substrates W may be placed on the first to fourth susceptors 141, 142, 143, and 144. Operations of the lift pins 161 will be described in detail hereinafter.

Also, the substrates W may be placed on the first to fourth susceptors 141, 142, 143, and 144 or separated from the support surfaces 147 of the first to fourth susceptors 141, 142, 143, and 144 as the holders 151 and 152 ascend and descend. Ascending and descending of the holders 151 and 152 will be described in detail hereinafter.

As illustrated in FIGS. 2 and 3, the chamber 120 has at least one exhaust port 124 formed on the edge of a bottom surface thereof, and the at least one exhaust port 124 is disposed on outer side of the susceptors 141, 142, 143, and 144. When the processes are performed, by-products and unreacted gas are discharged outwardly from the chamber 120 through the at least one exhaust port 124.

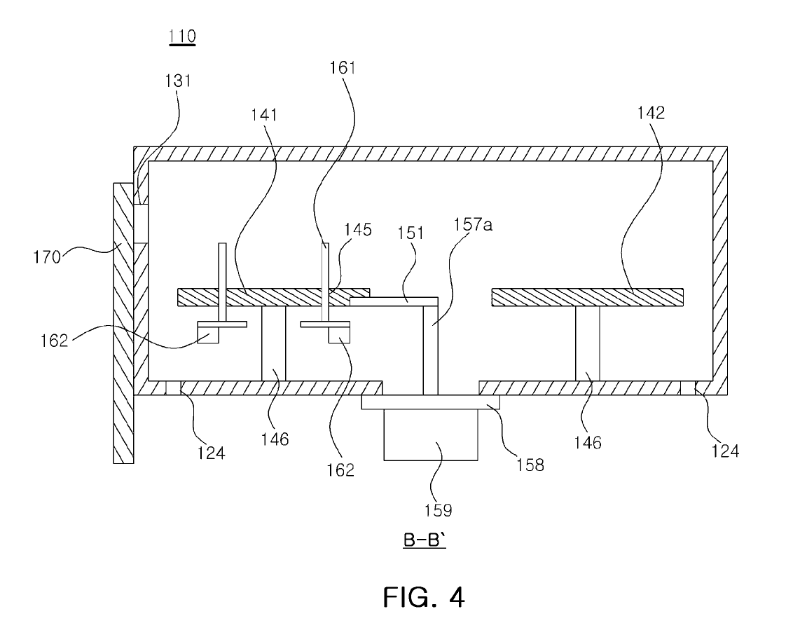

FIG. 4 is a cross-sectional view taken along line B-B of FIG. 2. A plurality of through holes 145 are formed to penetrate through the upper surfaces of the first and third susceptors 141 and 143. The lift pins 161 may be respectively installed below the first and third susceptors 141 and 143, and move through the through holes 145. Namely, as upper ends of the lift pins 161 penetrate through the through holes 145 so as to protrude from the upper surfaces of the first and third susceptors 141 and 143, the lift pins 161 may be positioned at a lift pin accommodation level as described hereinafter, and as the upper ends of the lift pins 161 are positioned within the through holes 145 or below the first and third susceptors 141 and 143, the lift pins 161 may be positioned at a lift pin loading level as described hereinafter. The lift pins 161 at the lift pin accommodation level may receive the substrates W from the substrate transfer robot 104, respectively, and as the lift pins 161 move to the lift pin loading level, the delivered substrates W are placed on the first and third susceptors 141 and 143.

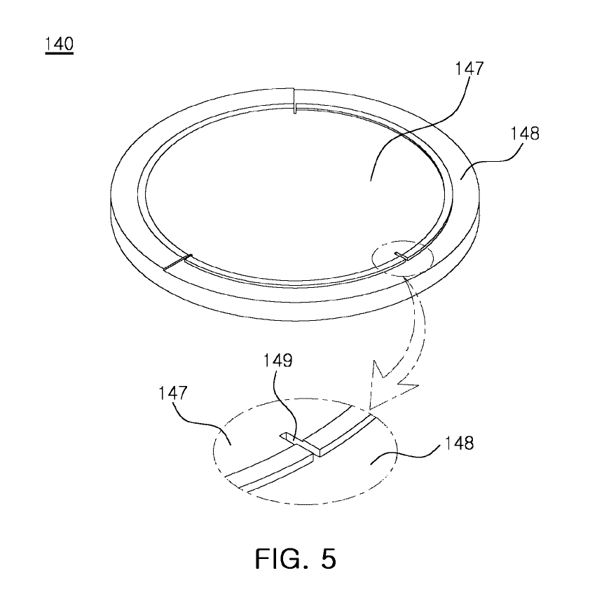

FIG. 5 is a view illustrating a susceptor illustrated in FIG. 2. Referring to FIG. 5, the susceptor 140 has the support surface 147, and the support surface 147 is substantially identical to a shape of the substrate W. An insertion recess 149 is recessed from the support surface 147, and as described hereinafter, when the holder 150 descends, the support pin 155a is inserted into the insertion recess 149. Similarly, an accommodation recess 148 is formed to be recessed lower than the support surface 147, and when the holder 150 descends, the fork 155 is accommodated within the accommodation recess 148. The insertion recess 149 may have a size and a shape substantially identical to those of the support pin 155a, and the accommodation recess 148 may have a size and a shape substantially identical to those of the fork 155. The susceptor 140 may include a heating plate (not shown) for heating the substrate W placed thereon during the process.

FIG. 6 is a view illustrating a holder illustrated in FIG. 2. The holder 150 includes the fork 155 and the support pin 155a. The fork 155 may have a circular arc shape having an inner diameter greater than a diameter of the substrate W. The fork 155 may have a circular arc shape having a central angle equal to or greater than 180°. In other words, the fork 155 may have a circular arc shape surrounding the edges of the substrate W, specifically, an arc shape. In addition, the fan shape may have a central angle equal to or greater than 180° to provide stability when the substrate W is picked up and transferred. The support pin 155a is connected to the fork 155 and protrudes to an inner side of the fork 155. The support pin 155a may be provided at least in the center and both ends of the fork 155. The substrate W placed on the holder 150 is positioned inwardly of the fork 155 and placed on an upper surface (or a mounting surface) of the support pin 155a. The substrate W may be stably supported by three support pins 155a disposed at equal angles of 120°. The holder 150 may have any shape other than that of the present exemplary embodiment.

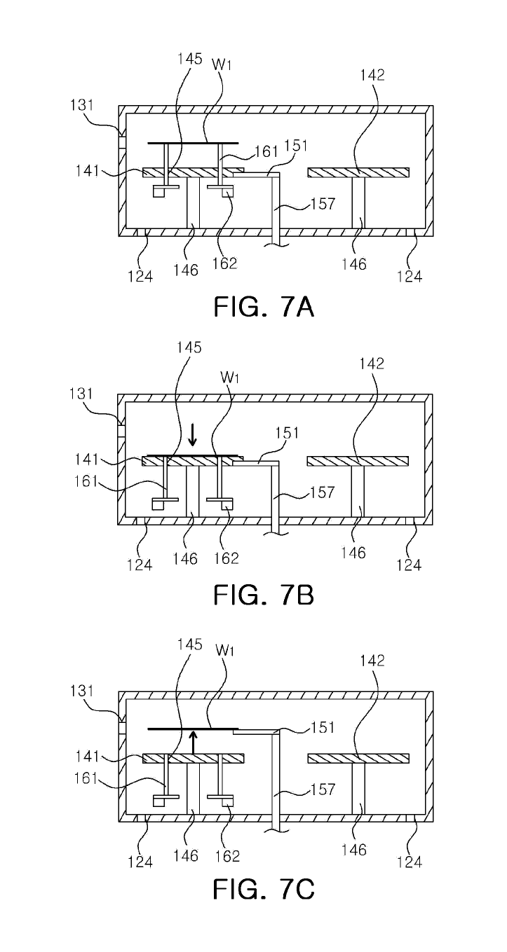

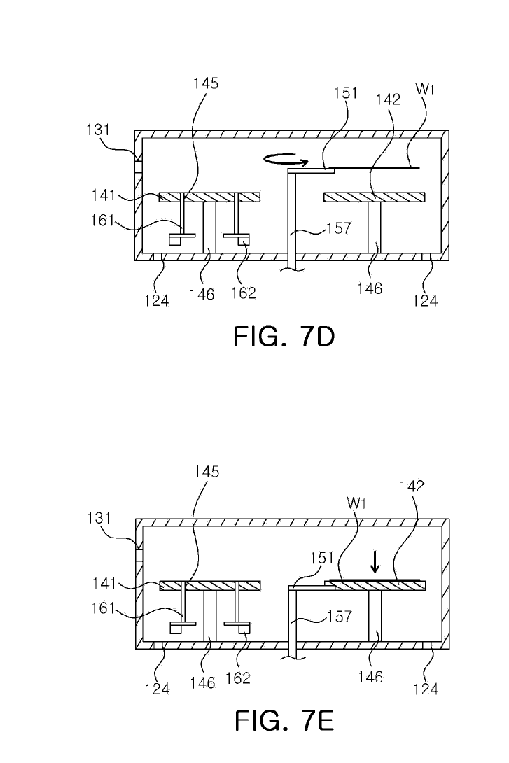

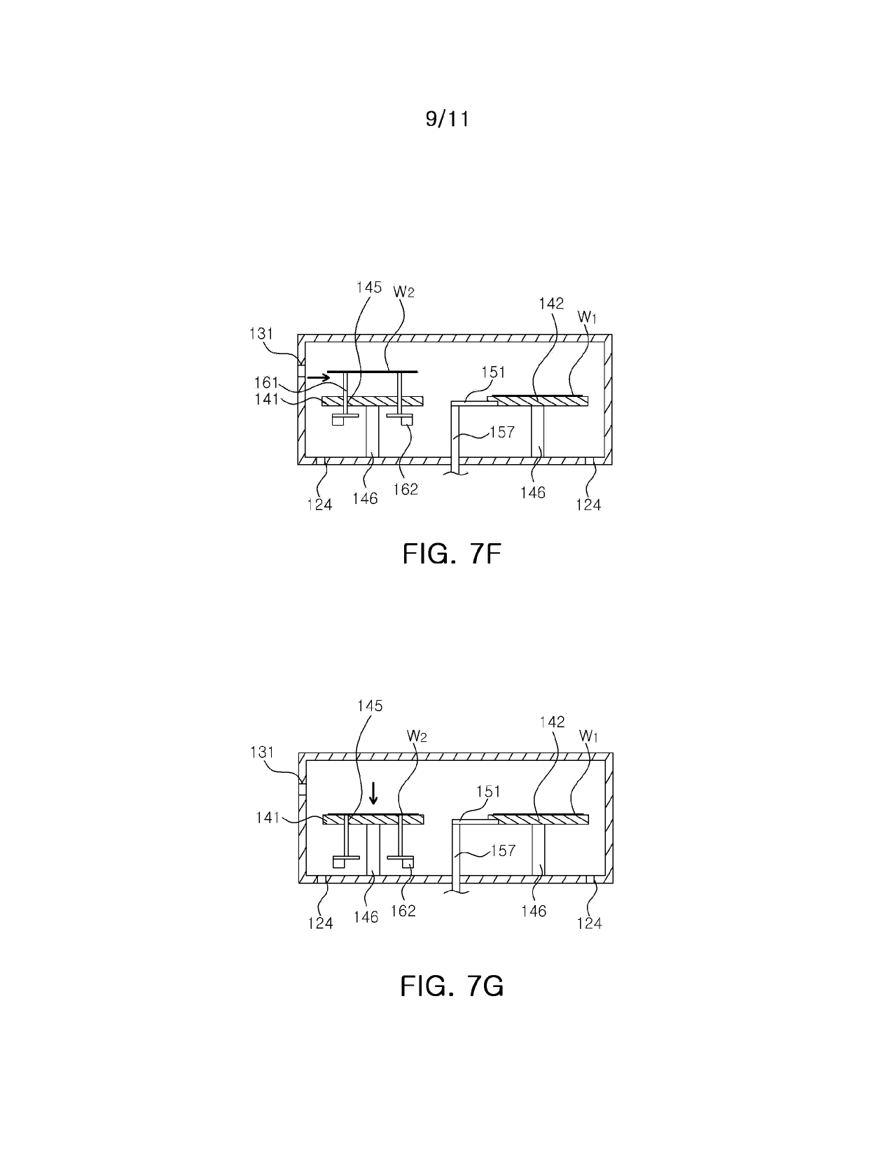

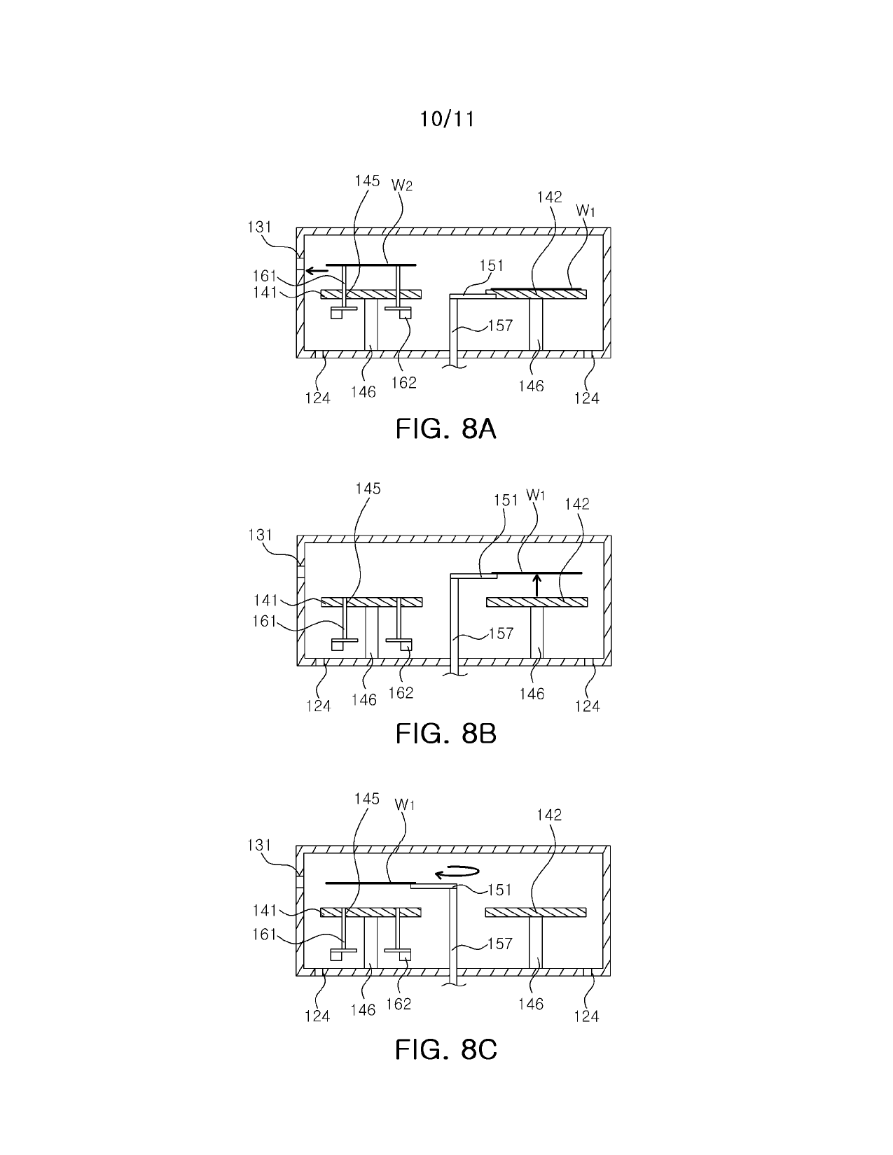

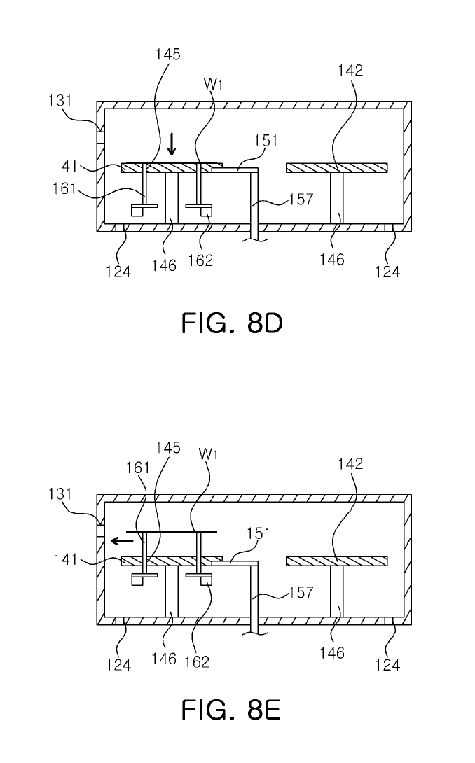

FIGS. 7A through 8E are views illustrating operations of the holder illustrated in FIG. 2. Hereinafter, a process of mounting the substrates W on the susceptors and a method of removing the substrates from the susceptors will be described with reference to FIGS. 7A through 8E. Hereinafter, only a single holder 15 and two susceptors 141 and 142 will be described, but these descriptions may also be applied in the same manner to the remaining holder 152 and susceptors 143 and 144.

Referring to FIGS. 7A through 8E, the lift pins 161 may be lifted or lowered by a lift pin driving module 162, and the fork 155 and the support pin 155a may be lifted or lowered by a holder driving module 159. Also, when the fork 155 is positioned at an accommodation level, the fork 155 may rotate to move to the delivery position.

As illustrated in FIG. 7A, a substrate W1 is placed on upper ends of the lift pins 161 through the first passage 131 by the substrate transfer robot 104. Here, the upper ends of the lift pins 161 are higher than the first susceptor 141 (“lift pin accommodation level”). In this case, the upper surfaces (or mounting surfaces) of the support pins 155a of the first holder 151 are lower than the support surface 147 of the first susceptor 141 (“holder loading level”), the support pins 155a are inserted into the insertion recesses 149, and the fork 155 is accommodated in the accommodation recess 148.

As illustrated in FIG. 7B, the upper ends of the lift pins 161 move to the lift pin loading level by the lift pin driving module 162. The substrate W1 is mounted on the support surface 147 of the first susceptor 141. Here, it is described that the substrate W1 is placed on the upper ends of the lift pins 161 and the upper ends of the lift pins 161 move to the lift pin loading level, but the present disclosure is not limited thereto and, in a state in which the upper ends of the lift pins 161 are placed in a position lower than the support surface 147 of the susceptor 141 (“lift pin loading level”) and the fork 155 and the support pins 155a are positioned to be higher than the susceptor 141 (“holder accommodation level”), the substrate W1 may be placed on the upper surfaces of the support pins 155a. In this case, the processes of FIGS. 7A and 7B may be omitted.

As illustrated in FIG. 7C, the first holder 151 is lifted to the holder accommodation level by the holder driving module 159. The substrate W1 is supported by the support pins 155a of the first holder 151 and positioned together with the support pins 155a at the holder accommodation level. As illustrated in FIG. 7D, the first holder 151 is rotated by the holder driving module 159 to move to the delivery position.

As illustrated in FIG. 7E, the first holder 151 placed in the delivery position is moved from the holder accommodation level to the holder loading level. The substrate W1 is mounted on the support surface 147 of the second susceptor 142. As illustrated in FIGS. 7F and 7G, the substrate W2 are placed on the upper ends of the lift pins 161 through the first passage 131 by the substrate transfer robot 104. In this case, the upper ends of the lift pins 161 are positioned at the lift pin accommodation level. The lifts 161 are lowered to the left pin loading level by the lift pin driving module 162.

As described above, when a single substrate W is put on each of two holders, the substrates W are delivered to the second and fourth susceptors 142 and 144 by the holders, and two other substrates are placed on the first and third susceptors 141 and 143 by the lift pins 161. Thereafter, processes are simultaneously performed on the substrates W, respectively.

Hereinafter, a process of unloading the substrates W from the chamber 120 after the processes performed on the substrates W are completed will be described with reference to FIGS. 8A through 8E.

As illustrated in FIG. 8A, the lift pins 161 of the first susceptor 141 are lifted to the lift pin accommodation level by the lift pin driving module 162. The substrate W2 placed on the first susceptor 141 is positioned at the lift pin accommodation level, and the substrate W is unloaded from the chamber 120 by the substrate transfer robot 104. Thereafter, the lift pins 161 of the first susceptor 141 are returned to the lift pin loading level and wait for a substrate W1.

As illustrated in FIG. 8B, the first holder 151 is moved from the holder loading height to the holder accommodation level by the holder driving module 159. The substrate W2 is positioned together with the support pints 155a of the first holder 151 at the holder accommodation level.

As illustrated in FIG. 8C, the first holder 151 rotates from the delivery position to move to the standby position. The first holder 151 is positioned at the holder accommodation level in the standby position. In this case, the substrate W2 is positioned at the holder accommodation level, and the substrate W2 may be unloaded from the chamber 120 by the substrate transfer robot 104.

As illustrated in FIG. 8D, the first holder 151 may be lowered by the holder driving module 159 so as to be positioned at the holder loading level. The substrate W2 is mounted on the support surface 147 of the first susceptor 141. As illustrated in FIG. 8E, the lift pins 161 of the first susceptor 141 are lifted from the lift pin loading level to the lift pin accommodation level by the lift pin driving module 162. The substrate W2 is positioned at the lift pin accommodation level, and the substrate W2 is unloaded from the chamber 120 by the substrate transfer robot 104.

As described above, the first holder and the third holder may rotate to place the substrates in the standby position or the delivery position, and the lift pins of the first susceptor and the second susceptor position the substrates at the lift pin loading level or the lift pin accommodation level, thus allowing the plurality of substrates to enter and exit the chamber.

As set forth above, according to exemplary embodiments of the present disclosure, a plurality of substrates may be effectively loaded into or unloaded from the chamber. Also, processes may be simultaneously performed on the plurality of substrates.

While exemplary embodiments have been shown and described above, it will be apparent to those skilled in the art that modifications and variations could be made without departing from the scope of the present invention as defined by the appended claims.

What is claimed is:

1. A substrate processing module comprising:
a chamber having a passage formed on one side thereof and allowing a substrate to enter or exit therethrough;
a first susceptor installed within the chamber, disposed in front of the passage, having at least one through hole formed in an upper surface thereof in a penetrating manner, and allowing the substrate to be placed thereon during a process;
a second susceptor installed within the chamber, disposed to the rear of the first susceptor, and allowing the substrate to be placed thereon during a process;
a rotary member provided within the chamber and rotating, based on a preset position;
a holder connected to the rotary member, rotating together with the rotary member, and having a mounting surface allowing the substrate to be placed thereon; and
a holder driving module connected to the rotary member and driving the rotary member to move the holder to a standby position corresponding to the first susceptor or to a delivery position corresponding to the second susceptor.

2. The substrate processing module of claim 1, further comprising:
at least one lift pin installed below the first susceptor and moving through the at least one through hole; and
a lift pin driving module connected to the at least one lift pin and moving the lift pins to a lift pin accommodation level and a lift pin loading level,
wherein an upper end of the at least one lift pin is positioned to be higher than the first susceptor at the lift pin accommodation level and the mounting surface is positioned to be lower than the upper surface of the first susceptor at the lift pin loading height.

3. The substrate processing module of claim 1, wherein the rotary member is disposed in the center of the length of the chamber and at the end of the width of the chamber.

4. The substrate processing module of claim 1, wherein the holder driving module lifts the rotary member to move the holder to a holder accommodation level and a holder loading level, the holder is positioned to be higher than the first and second susceptors at the holder accommodation level, and the mounting surface is positioned to be lower than the upper surfaces of the first and second susceptors at the holder loading level.

5. The substrate processing module of claim 4, wherein the holder, placed at the holder accommodation level, moves to the delivery position.

6. The substrate processing module of claim 4, wherein the holder comprises:
a fork having an arc shape and opened to an outside of the chamber; and
one or more support pins connected to the fork, protruding toward an inner side of the fork, and proving the mounting surface,
wherein the first and second susceptors have one or more insertion recesses to which the one or more support pins are inserted when the holder positioned above moves to the holder loading level.

7. The substrate processing module of claim 6, wherein a central angle of the fork having a fan shape is equal to or greater than 180°.

8. The substrate processing module of claim 6, wherein the first and second susceptors have support surfaces allowing the substrates to be placed thereon, and the one or more insertion recesses are formed on the edges of the support surfaces.

9. A substrate processing module comprising:
a chamber having a first process space and a second process space divided by a partition and having a first passage and a second passage formed on one side thereof and allowing substrates to enter and exit the first process space and the second process space, respectively;
first and third susceptors installed within the chamber, disposed in front of the first passage and in front of the second passage, respectively, having at least one through hole formed in upper surfaces thereof in a penetrating manner, and allowing the substrates to be placed thereon during a process;
second and fourth susceptors installed within the chamber, disposed to the rear of the first susceptor and the third susceptor, respectively, and allowing the substrates to be placed thereon during a process;
a first rotary member and a second rotary member installed within the chamber, and rotating, based on preset positions, respectively;
a first holder connected to the first rotary member to rotate together therewith and having a mounting surface allowing the substrates to be placed thereon;
a second holder connected to the second rotary member to rotate together therewith and having a mounting surface allowing the substrates to be placed thereon;
a first holder driving module connected to the first rotary member to drive the first rotary member, and moving the first holder to a first standby position corresponding to the first susceptor or a first delivery position corresponding to the second susceptor;
a second holder driving module connected to the second rotary member to drive the second rotary member, and moving the second holder to a second standby position corresponding to the third susceptor or a second delivery position corresponding to the fourth susceptor;
at least one lift pin installed below the first and third susceptors, respectively, and moving through the at least one through hole; and
a lift pin driving module connected to the at least one lift pin and moving the at least one lift pin between a lift pin accommodation level and a lift pin loading level,
wherein an upper end of the at least one lift pin is positioned to be higher than the first and third susceptors at the lift pin accommodation level, and the mounting surface is positioned to be lower than the upper surfaces of the first and third susceptors at the lift pin loading level.

10. A substrate processing apparatus comprising:
a load lock chamber allowing a substrate transferred from the outside to be placed thereon and having an interior changing from a vacuum state to an atmospheric pressure state;
a substrate processing module performing processing on the substrate; and
a substrate transfer module disposed between the load lock chamber and the substrate processing module and having a substrate transfer robot transferring the substrate between the load lock chamber and the substrate processing module,
wherein the substrate processing module comprises:
a chamber having a passage formed on one side thereof and allowing a substrate to enter or exit therethrough;
a first susceptor installed within the chamber, disposed in front of the passage, having at least one through hole formed in an upper surface thereof in a penetrating manner, and allowing the substrate to be placed thereon during a process;
a second susceptor installed within the chamber, disposed to the rear of the first susceptor, and allowing the substrate to be placed thereon during a process;
a rotary member provided within the chamber and rotating, based on a preset position;
a holder connected to the rotary member, rotating together with the rotary member, and having a mounting surface allowing the substrate to be placed thereon; and
a holder driving module connected to the rotary member and driving the rotary member to move the holder to a standby position corresponding to the first susceptor or to a delivery position corresponding to the second susceptor.

11. The substrate processing apparatus of claim 9, wherein the substrate processing module comprises:
at least one lift pin installed below the first and third susceptors, respectively, and moving through the at least one through hole; and
a lift pin driving module connected to the at least one lift pin and moving the lift pins to a lift pin accommodation level at which an upper end of the at least one lift pin is position to be higher than the first and third susceptors, and to a lift pin loading level at which the mounting surface is positioned to be lower than the upper surfaces of the first and third susceptors.

12. A substrate transferring method for transferring a substrate by using the substrate processing module of claim 1, the substrate transferring method comprising:
a first mounting operation of placing a first substrate on a first susceptor;
a first changing operation of changing a holder in a standby position from a holder loading level to a holder accommodation level;
a first moving operation of rotating the holder to move to a delivery position;
a second changing operation of changing the holder in the delivery position from the holder accommodation level to the holder loading level; and
a second mounting operation of placing a second substrate on the first susceptor.

13. The substrate transferring method of claim 12, further comprising:
a first releasing operation of releasing the second substrate from the first susceptor;
a third changing operation of moving the holder in the delivery position from the holder loading level to the holder accommodation level;
a second moving operation of rotating the holder to move to the standby position;
a fourth changing operation of moving the holder in the standby position from the holder accommodation level to the holder loading level; and
a first releasing operation of releasing the first substrate from the upper portion of the first susceptor.

14. The substrate transferring method of claim 12, wherein the first mounting operation is an operation of lifting lift pins to a lift pin accommodation level, placing the first substrate on upper ends of the lift pins at the lift pin accommodation level, and moving the lift pins to a lift pin loading level.

15. The substrate transferring method of claim 12, wherein the second mounting operation is an operation of lifting lift pins to a lift pin accommodation level, placing the second substrate on upper ends of the lift pins at the lift pin accommodation level, and moving the lift pins to a lift pin loading level.
